(19) United States
(12) Patent Application Publication
(10) Pub. No.: US 2006/0076614 A1
(43) Pub. Date: Apr. 13, 2006

(54) Semiconductor device

(75) Inventor: Hitoshi Ninomiya, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/220,678

(22) Filed: Sep. 8, 2005

(30) Foreign Application Priority Data
Sep. 24, 2004 (JP) 2004-277562

(51) Int. Cl. H01L 29/94

(52) U.S. Cl. 257/330

(57) ABSTRACT

A semiconductor device well balanced between high voltage applicability and low ON resistance, includes an n⁺-type semiconductor substrate; an n-type drift region formed thereon; a p-type base region formed on the n-type drift region; a plurality of p-type column regions in the n-type drift region so as to contact with the p-type base region and having a predetermined depth in a direction perpendicular to the p-type base region; a plurality of gate electrodes spaced by a regular distance from the centers, as viewed in the depth-wise direction, of each p-type column region, and penetrating the p-type base region, and partly buried in the n-type drift region; n-type source regions provided in the surficial region of the p-type base region around each of the gate electrodes; a drain electrode connected to the back surface of the n⁺-type semiconductor substrate; and a source electrode connected to the n-type source regions.

This application is based on Japanese patent application No. 2004-277562 the content of which is incorporated hereinto by reference.

### DISCLOSURE OF THE INVENTION

1. Field of the Invention

The present invention relates to a semiconductor device, and in particular to a semiconductor device having a high-voltage-applicable MOSFET structure.

2. Related Art

In general, semiconductor devices are roughly classified into lateral-type ones having electrode portions on one surface thereof, and vertical-type ones having electrode potions on both surfaces. A special topic on the vertical-type semiconductor devices is such that both of direction in which the drift current flows during the ON time, and direction in which a depletion layer extends as being affected by a reverse bias voltage during the OFF time are aligned in the thickness-wise direction of a substrate (vertical direction). In an effort of raising voltage resistance of the vertical-type semiconductor devices in which current is applied between the electrodes provided on two opposing surfaces, it has been necessary to increase specific resistivity and thickness of a high-resistivity layer between both electrodes. For this reason, a semiconductor device having a higher voltage applicability will have a larger ON resistance, indicating trade-off relationship between the high voltage applicability and ON resistance. In order to realize low-power-consumption devices, it is necessary to achieve low ON resistance while keeping high voltage applicability.

Japanese Laid-Open Patent Publication “Tokkai” No. 2001-298190 (p. 22, FIG. 1(b)) discloses a power MOSFET succeeded in realizing high voltage applicability, in which a drift layer is provided on a semiconductor substrate and under a gate electrode, and a partition region, which is a column layer, is provided under the base region, two these layers being configured so as to contact with the drain layer to thereby allow them to function as electric field relaxation layers.

Japanese Laid-Open Patent Publication “Tokkai” No. 2000-260984 (p. 9, FIG. 4) discloses a power MOSFET succeeded in realizing high voltage applicability through adoption of a super-junction structure, in which a drift region and a column region, which function as electric field relaxation layers composed of a p-n junction portion, is provided between a drain region and a base region, and also succeeded in realizing low ON resistance by vertically arranging a source region, the base region and the drift region, and by providing a gate electrode along these layers, so as to allow the portion of the base region, facing to the gate electrode, to invert itself to thereby form a channel plane during the ON time.

The technique described in Japanese Laid-Open Patent Publication “Tokkai” No. 2001-298190 relates to a planar structure in which the gate electrode lies flat in the direction of the main surface of the semiconductor device, so that when voltage is applied from the drain electrode towards the gate electrode, that is during the ON time, a depletion layer generates in a portion of the drift region under the gate electrode and between the adjacent base regions, and as a consequence, this considerably narrows a current path towards the gate electrode, generates so-called junction FET resistance, and increases the ON resistance. This means that the more the gate electrode is downsized, or the more the distance between the base regions is shortened, the more the junction resistance is non-negligible, so that it was difficult to downsize the semiconductor device per unit cell, if reduction in the ON resistance was aimed at.

The technique described in Japanese Laid-Open Patent Publication “Tokkai” No. 2000-260984 relates to a configuration of vertical-type MOSFET having a trench-formed gate electrode extending in one direction, and would be more successful in realizing low ON resistance as compared with the semiconductor device described in Japanese Laid-Open Patent Publication “Tokkai” No. 2001-298190, even if the downsizing should be effected in the lateral direction, or in the direction of arrangement of the gate electrodes. The downsizing in the in-plane, depth-wise direction will, however, result in shortening of the channel plane produced in the vicinity of the junction interface between the gate electrode and the base region during the ON time, and will consequently make it difficult to reduce the ON resistance. Further improvement has therefore been required.

### SUMMARY OF THE INVENTION

According to the present invention, there is provided a semiconductor device comprising:

a first-conductivity-type semiconductor substrate;

a first-conductivity-type drift region formed on the surface of the first-conductivity-type semiconductor substrate;

a second-conductivity-type base region formed on the surface of the first-conductivity-type drift region,

a plurality of second-conductivity-type column regions provided in the first-conductivity-type drift region so as to contact with the second-conductivity-type base region and to have a predetermined depth in a direction perpendicular to the second-conductivity-type base region;

a plurality of gate electrodes provided so as to be spaced by a regular distance from the centers, as viewed in the depth-wise direction, of each of the second-conductivity-type column regions, and to penetrate the second-conductivity-type base region, as being buried in part of the first-conductivity-type drift region;

first-conductivity-type source regions provided in the surficial region of the second-conductivity-type base region around each of the gate electrodes;

a drain electrode connected to the back surface of the first-conductivity-type semiconductor substrate; and

a source electrode connected to the first-conductivity-type source regions;

wherein in-plane positions of the second-conductivity-type column regions are determined so that the centers, as viewed in the depth-wise direction, of every adjacent columns are spaced by a regular distance;

the gate electrode is formed with a trench geometry so as to surround the second-conductivity-type column region; and

channel planes produced under a reverse bias voltage applied between the drain electrode and the source electrode in the OFF state are configured to be a equivalent surface orientation.

In the present invention, under no bias applied between the gate electrode and the source electrode, and under a reverse bias is applied between the drain electrode and the source electrode, a depletion layer extends from three junctions respectively between the first-conductivity-type drift region and the second-conductivity-type base region, between the first-conductivity-type drift region and the second-conductivity-type column regions, and optionally between the second-conductivity-type column regions and the first-conductivity-type semiconductor substrate, so as to inhibit current flow between the drain electrode and the source electrode, that is, to establish the OFF state.

On the other hand, when the bias voltage is applied between the gate electrodes and the source electrode, the surface of the second-conductivity-type base region facing to the gate electrode comes into an inverted state, the channel is formed, and thereby current flows corresponding to the voltage applied between the drain electrode and the source electrode, that is, the ON state is established.

Another advantage is that the regular distance between the individual second-conductivity-type column regions can avoid non-uniformity in the charge balance, and so that high voltage applicability by virtue of the super-junction structure is realized. On the other hand, by making the channel plane formed by the trench-formed gate electrodes have the same surface orientation, it is made possible to select a surface orientation capable of minimizing the ON resistance under a fixed channel width, and this is successful in realizing low ON resistance even when the semiconductor is downsized. As is clear from the above, it is made possible to optimize the balance between high voltage applicability and low ON resistance. This successfully maximizes the breakdown voltage while minimizing the ON resistance.

The present invention makes it possible to provide a semiconductor device well balanced between high voltage applicability and low ON resistance, and adapted to downsizing.

### BRIEF DESCRIPTION OF THE DRAWINGS

The above and other objects, advantages and features of the present invention will be more apparent from the following description taken in conjunction with the accompanying drawings, in which:

FIG. 1 is a sectional view of a semiconductor device of one embodiment;

FIG. 2 is a plan view of the semiconductor device of the above embodiment; and

FIG. 3 is a drawing showing state of electric field in an electric field relaxation layer of the semiconductor device of the above embodiment.

### DETAILED DESCRIPTION OF THE INVENTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

The following paragraphs will describe one embodiment of a semiconductor device of the present invention, referring to the attached drawings.

It is to be noted that any common components in the drawings will be given with the same reference numerals, so as to dispense with repetitive explanation.

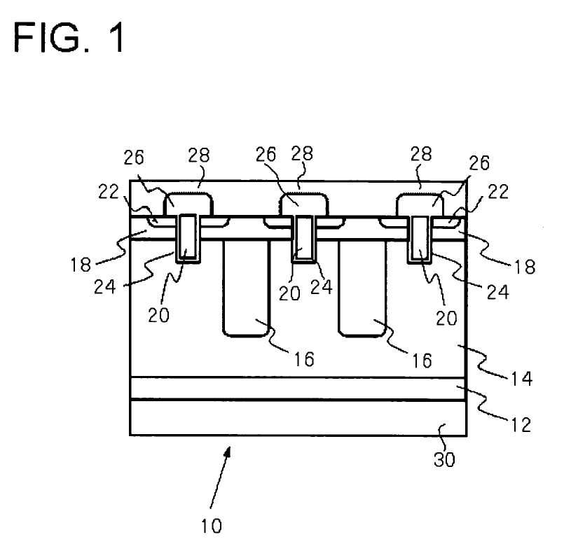

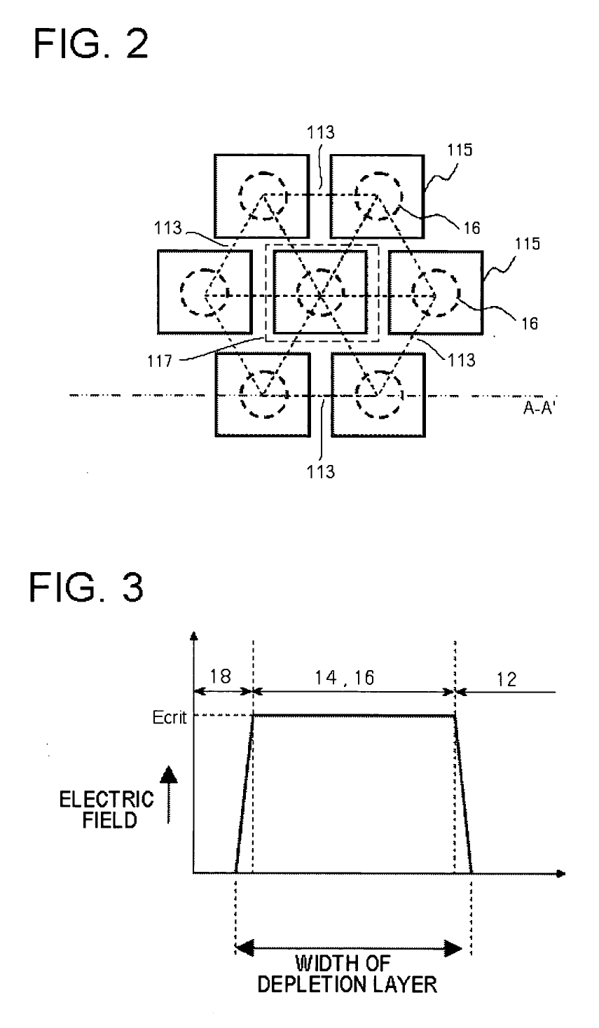

FIG. 1 is a sectional view of a semiconductor device of this embodiment, and FIG. 2 is a plan view of the semiconductor device shown in FIG. 1. FIG. 1 is a sectional view taken along line A-A′ in FIG. 2.

In this semiconductor device 10, an n⁺-type semiconductor substrate 12 which corresponds to the first-conductivity-type semiconductor substrate is composed of a high-concentration, n-type semiconductor, has an n-type drift region 14 as the first-conductivity-type drift region provided on one surface thereof, and has a drain electrode 30 composed of a metal electrode provided on the other surface thereof.

The n-type drift region 14 is composed of an epitaxial layer formed by growing silicon on the surface of the n⁺-type semiconductor substrate 12, while being doped with phosphorus, for example. Further on the surface of the n-type drift region 14, a p-type base region 18 as the second-conductivity-type base region is formed.

In the n-type drift region 14, there are provided a plurality of p-type column regions 16 as the second-conductivity-type column regions. The p-type column regions 16 are provided so as to contact with the p-type base region 18 and to have a predetermined depth in a direction perpendicular to the p-type base region 18. Every adjacent p-type column regions 16 in a plan view, as shown in FIG. 2, are arranged so that the centers thereof, as viewed in the depth-wise direction, are spaced by a regular distance. For example, a triangle given by connecting the centers of three p-type column regions 16 adjacent to each other will be an equilateral triangle. The p-type column regions 16 shown in FIG. 1 are formed so as to fall within the n-type drift region 14 rather than reaching the n⁺-type semiconductor substrate 12, but it is also allowable to form it so as to penetrate the n-type drift region 14 and to reach the n⁺-type semiconductor substrate 12.

The gate electrodes 20 are provided as being spaced by a regular distance from the centers, as viewed in the depth-wise direction, of each of the p-type column regions 16, and where a trench pattern 113 (see FIG. 2) is formed so as to surround the p-type column regions 16. Each of the gate electrodes 20 are formed also so as to penetrate the p-type base region 18, and so as to be buried in part of the n-type drift region 14, and is faced to the n-type drift region 14, the p-type base region 18 and an n-type source region 22 described later, through a gate oxide films 24 placing in between.

On the surficial region of the p-type base region 18, there are provided n-type source regions 22 as the first-conductivity-type source regions around each of the gate electrodes 20. A source electrode 28 is connected to the n-type source regions 22 and the p-type base region 18. The source electrode 28 is faced to each of the gate electrodes 20 through the corresponding insulating films 26 placing in between, and is not electrically connected therewith.

In the semiconductor device 10, when no bias is applied between the gate electrodes 20 and the source electrode 28, and a reverse bias is applied between the drain electrode 30 and the source electrode 28, a depletion layer extends from each junction respectively between the n-type drift region 14 and the p-type base region 18, and between the n-type drift region 14 and the p-type column regions 16, and from the p-type column regions 16 to the n⁺-type semiconductor substrate 12, so as to inhibit current flow between the drain electrode 30 and the source electrode 28, that is, to establish the OFF state.

At this time, the entire portions of the n-type drift region 14 and the p-type column regions 16 may function as an electric field relaxation layer, and the depletion layer extends from these junction planes, so that entire portions of the n-type drift region 14 and the p-type column regions 16 are depleted.

The p-type column regions 16 are free from fear of causing non-uniformity in charge balance as the electric field relaxation layers, because the centers, as viewed in the depth-wise direction, of every adjacent ones are spaced by a regular distance. The present inventors have found, as shown in FIG. 3, that the state of electric field at the junction planes, between the n-type drift region 14 and the p-type column regions 16, which are electric field relaxation layers, becomes uniform over the entire area ranging from the p-type base region 18 to the n⁺-type semiconductor substrate 12, irrespective of whether these junction planes extending from the p-type base region 18 reach the n⁺-type semiconductor substrate 12 or not. This successfully realizes high voltage applicability by virtue of the super-junction structure having the p-type column regions 16 and n-type drift region 14 alternately formed therein.

The present inventors have also found that the width of the trench pattern 113 can be minimized, and so that the distance between the centers of every adjacent p-type column regions 16 as viewed in the depth-wise direction can be equalized, by making a unit cell 117 in a plan view as shown in FIG. 2 (an area surrounded by the median line of the trench pattern 113 composed of the gate electrode surrounding the p-type column region 16) have a rectangular geometry with a ratio of the long edge and the short edge of approximately 2:✓3. The minimization of the distance between every adjacent unit cells makes it possible to downsize the semiconductor device while realizing high voltage applicability.

Under application of the bias voltage between the gate electrodes 20 and the source electrode 28, the surficial region of the p-type base region 18 facing to the gate electrode 20 is inverted to form a channel, and allows current to flow therethrough corresponding to the voltage applied between the drain electrode 30 and the source electrode 28, establishing the ON state of the semiconductor device.

The gate electrodes 20 herein are formed, as shown in FIG. 2, in conformity with the trench pattern 113, so that the plane where the gate electrodes 20 and the p-type base region 18 are faced can be understood as channel planes 115. The channel planes 115 respectively have an equivalent surface orientation so as to surround the p-type column regions 16, so that it is made possible to select a surface orientation capable of minimizing the ON resistance when width of a region where the channels are formed (channel width) is fixed.

It has generally been known that the downsizing of the semiconductor device results in a short channel width and consequently increases the ON resistance, whereas the present inventors have found that mobility of electric charge (carrier) can be maximized when the channel plane has a surface orientation equivalent to Si(100) plane, so that low ON resistance can be realized even if the semiconductor device is downsized.

The semiconductor device shown in FIG. 1 and FIG. 2 can be fabricated as described below.

First, the n⁺-type semiconductor substrate 12, which is a silicon substrate with a high impurity content, is obtained, and silicon is then epitaxially grown on the surface of the substrate 12 while doping phosphorus, for example, to thereby form the n-type drift region 14. The n-type drift region 14 herein is adjusted so as to have an impurity concentration lower than that of the n⁺-type semiconductor substrate 12.

Next, the p-type base region 18 is formed on the surface of the n-type drift region 14, the gate trench is formed, the gate oxide insulating film 24 is formed on the inner wall surface of the trench, and the gate electrodes 20 are formed therein. High-energy ion implantation is then targeted at predetermined positions to thereby form the p-type column regions 16. The p-type column regions 16 herein may be formed prior to formation of the p-type base region 18.

The n-type source regions 22 are then formed in the surficial region of the p-type base region 18, the insulating film 26 is formed, so as to completely cover the gate electrodes, and the source electrode 28 is formed typically using aluminum so as to cover the insulating film 26, the n-type source regions 22 and the p-type base region 18. On the other hand, the drain electrode 30 is formed using a predetermined metal on the back surface of the n⁺-type semiconductor substrate 12.

As has been described in the above, the semiconductor device of this embodiment makes it possible to downsize itself, and at the same time to optimize the balance between high voltage applicability and low ON resistance. In short, it is made possible to provide a small-sized semiconductor device capable of maximizing the breakdown voltage while minimizing the ON resistance.

The above-described embodiment explained the semiconductor device using the high-concentration, n-type semiconductor substrate, and having the column regions composed of the p-type semiconductor layer formed in the drift region composed of the n-type semiconductor layer, whereas similar effects can of course be obtained by a semiconductor device having n-type and p-type semiconductor layers exchanged therein.

It is apparent that the present invention is not limited to the above embodiments that may be modified and changed without departing from the scope and spirit of the invention.

What is claimed is:

1. A semiconductor device comprising:
a first-conductivity-type semiconductor substrate;
a first-conductivity-type drift region formed on the surface of said first-conductivity-type semiconductor substrate;
a second-conductivity-type base region formed on the surface of said first-conductivity-type drift region,
a plurality of second-conductivity-type column regions provided in said first-conductivity-type drift region so as to contact with said second-conductivity-type base region and to have a predetermined depth in a direction perpendicular to said second-conductivity-type base region;
a plurality of gate electrodes provided so as to be spaced by a regular distance from the centers, as viewed in the depth-wise direction, of each of said second-conductivity-type column regions, and to penetrate said second-conductivity-type base region, as being buried in part of said first-conductivity-type drift region;
first-conductivity-type source regions provided in the surficial region of said second-conductivity-type base region around each of said gate electrodes;
a drain electrode connected to the back surface of said first-conductivity-type semiconductor substrate; and
a source electrode connected to said first-conductivity-type source regions;
wherein in-plane positions of said second-conductivity-type column regions are determined so that the centers, as viewed in the depth-wise direction, of every adjacent columns are spaced by a regular distance;
said gate electrode is formed with a trench geometry so as to surround said second-conductivity-type column region; and
channel planes produced under a reverse bias voltage applied between said drain electrode and said source electrode in the OFF state are configured to be a equivalent surface orientation.

2. The semiconductor device according to claim 1, wherein each of said channel planes has a surface orientation equivalent to Si(100) plane.

3. The semiconductor device according to claim 1, wherein a unit cell in the plan view has a rectangular geometry, having a ratio of the long edge and the short edge of approximately 2:✓3.
